(19) United States
(12) Patent Application Publication
(10) Pub. No.: US 2025/0327872 A1
(43) Pub. Date: Oct. 23, 2025

(54) BATTERY PACK AND MODULE HEALTH STATUS CHECK FOLLOWING AN IMPACT EVENT

(71) Applicant: GM Global Technology Operations LLC, Detroit, MI (US)

(72) Inventor: Andrew Geoffrey Balding, Wixom, MI (US)

(21) Appl. No.: 18/638,040

(22) Filed: Apr. 17, 2024

(51) Int. Cl. G01R 31/392; G01R 31/367; H01M 10/42; H01M 10/48

(52) U.S. Cl. CPC G01R 31/392; G01R 31/367; H01M 10/4285; H01M 10/48; H01M 2010/4271; H01M 2010/4278; H01M 2220/20

(57) ABSTRACT

A vehicle includes a system for diagnosing a health of a battery unit of a vehicle. The battery unit can be a battery pack of the vehicle or a battery module of the battery pack. A vehicle dynamics sensor measures vehicle dynamics data for the vehicle during a time period in which an impact event occurs at the vehicle. An accelerometer obtains a battery unit acceleration data for the battery unit during the period. A processor determines an inertial load on the battery unit from the vehicle dynamics data and the battery unit acceleration data, compares the inertial load to a threshold determined using a virtual model of the battery unit to determine a health status of the battery unit, and performs a remedial action for the battery unit based on the health status.

### INTRODUCTION

The subject disclosure relates to a method of diagnosing the health of a battery pack and, more specifically, to determining the health of the battery pack after an occurrence of an impact event at the vehicle.

An electric vehicle is powered from a battery pack that may include a plurality of cells, cell arrays, sub-assemblies or battery modules. During an impact event on the vehicle, the battery pack can endure physical damage. If the physical damage is minor, the battery pack can still be used without any impairment to the operation of the electrical vehicle. However, considerable damage to the battery pack can require servicing. Accordingly, it is desirable to provide for diagnosing a health status of battery cells, modules, or other related sub-systems that may be part of a battery pack in order to determine a remedial action after an impact event.

### SUMMARY

In one exemplary embodiment, a method for diagnosing a health of a battery pack of a vehicle is disclosed. Vehicle dynamics data for the vehicle is obtained during a time period in which an impact event occurs at the vehicle. Battery unit acceleration data is obtained for a battery unit of the vehicle during the time period. An inertial load on the battery unit is determined from the vehicle dynamics data and the battery unit acceleration data. The inertial load is compared to a threshold determined using a virtual model of the battery unit to determine a health status of the battery unit. A remedial action for the battery unit is performed based on the health status.

In addition to one or more of the features described herein, the method further includes simulating the impact event using the virtual model to determine the threshold.

In addition to one or more of the features described herein, the method further includes simulating the impact event offline and determining the health status online.

In addition to one or more of the features described herein, the method further includes determining the health based on a magnitude of the inertial load and a direction of the inertial load.

In addition to one or more of the features described herein, the method further includes obtaining the vehicle dynamics data in a vehicle-centered frame of reference and obtaining the battery unit acceleration data in a unit-centered frame of reference.

In addition to one or more of the features described herein, performing the remedial action further includes at least one of sending a signal indicating the health of the battery unit, sending the signal instructing an operator of the battery unit, shutting down the battery unit, and shutting down a battery pack.

In addition to one or more of the features described herein, wherein the battery unit includes a plurality of battery units, the method further includes obtaining the battery unit acceleration data for each of the plurality of battery units, determining the health status for each of the plurality of battery units based on the respective battery unit acceleration data and performing the remedial action for each battery unit based on the health status of the respective battery unit.

In another exemplary embodiment, a system for diagnosing a health of a battery unit of a vehicle is disclosed. The system includes a vehicle dynamics sensor for measuring vehicle dynamics data for the vehicle during a time period in which an impact event occurs at the vehicle, an accelerometer for obtaining a battery unit acceleration data for the battery unit during the time period, and a processor. The processor is configured to determine an inertial load on the battery unit from the vehicle dynamics data and the battery unit acceleration data, compare the inertial load to a threshold determined using a virtual model of the battery unit to determine a health status of the battery unit, and perform a remedial action for the battery unit based on the health status.

In addition to one or more of the features described herein, the processor is further configured to simulate the impact event using the virtual model to determine the threshold.

In addition to one or more of the features described herein, the processor is further configured to simulate the impact event offline and determine the health status online.

In addition to one or more of the features described herein, the processor is further configured to determine the health based on a magnitude of the inertial load and a direction of the inertial load.

In addition to one or more of the features described herein, the vehicle dynamics sensor is configured to measure the vehicle dynamics data in a vehicle-centered frame of reference and the accelerometer is configured obtain the battery unit acceleration data in a unit-centered frame of reference.

In addition to one or more of the features described herein, the processor is further configured to perform the remedial action by performing at least one of sending a signal indicating the health of the battery unit, sending the signal instructing an operator of the battery unit, shutting down the battery unit, and shutting down a battery pack.

In addition to one or more of the features described herein, the battery unit includes a plurality of battery units and the processor is further configured to obtain the battery unit acceleration data for each of the plurality of battery units, determine the health status for each of the plurality of battery units based on the respective battery unit acceleration data and perform the remedial action for each battery unit based on the health status of the respective battery unit.

In yet another exemplary embodiment, a vehicle is disclosed. The vehicle includes a battery pack, a vehicle dynamics sensor for measuring vehicle dynamics data for the vehicle during a time period in which an impact event occurs at the vehicle, an accelerometer for obtaining a battery unit acceleration data for a battery module of the battery pack during the time period, and a processor. The processor is configured to determine an inertial load on the battery module from the vehicle dynamics data and the battery unit acceleration data, compare the inertial load to a threshold determined using a virtual model of the battery pack to determine a health status of the battery pack, and perform a remedial action for the battery pack based on the health status.

In addition to one or more of the features described herein, the processor is further configured to simulate the impact event using the virtual model to determine the threshold.

In addition to one or more of the features described herein, the processor is further configured to simulate the impact event offline and determine the health status online.

In addition to one or more of the features described herein, the processor is further configured to determine the health status of the battery pack based on a magnitude of the inertial load and a direction of the inertial load.

In addition to one or more of the features described herein, the vehicle dynamics sensor is configured to measure the vehicle dynamics data in a vehicle-centered frame of reference and the accelerometer is configured to obtain the battery unit acceleration data in a unit-centered frame of reference.

In addition to one or more of the features described herein, the processor is further configured to perform the remedial action by performing at least one of sending a signal indicating the health status of the battery pack, sending the signal instructing an operator of the battery module, shutting down the battery module, and shutting down the battery pack.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 shows a vehicle in accordance with an exemplary embodiment;

FIG. 2 shows a battery health diagnosis system of the vehicle, in an embodiment; and

FIG. 3 is a flowchart of a method of operating a battery pack of a vehicle, in an illustrative embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features.

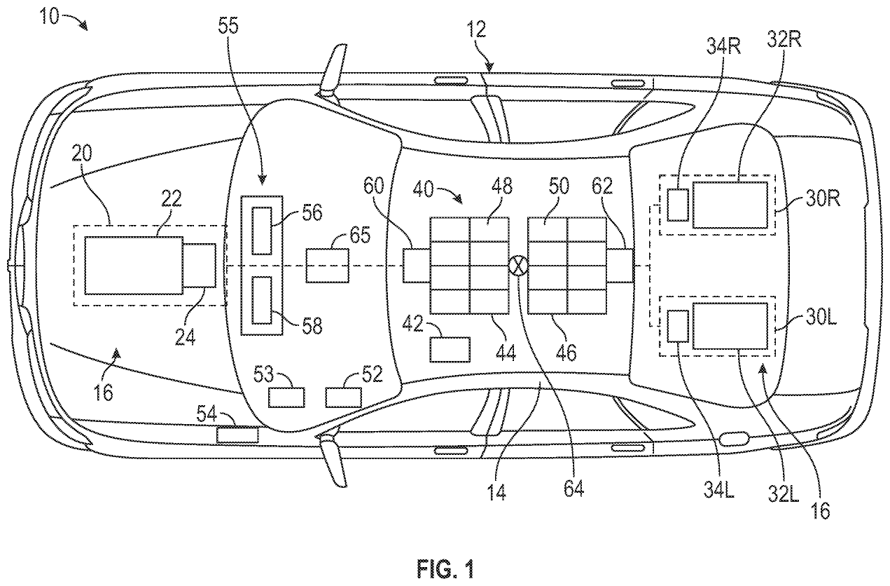

In accordance with an exemplary embodiment, FIG. 1 shows an embodiment of a vehicle 10, which includes a vehicle body 12 defining, at least in part, an occupant compartment 14. The vehicle body 12 also supports various vehicle subsystems including a propulsion system 16, and other subsystems to support functions of the propulsion system 16 and other vehicle components, such as a braking subsystem, a suspension system, a steering subsystem, and others.

The vehicle 10 may be an electrically powered vehicle (EV), a gas-powered vehicle, a hybrid vehicle or any other vehicle that operates using a battery pack. In an embodiment, the vehicle 10 is an electric vehicle that includes multiple motors and/or drive systems. Any number of drive units may be included, such as one or more drive units for applying torque to front wheels (not shown) and/or to rear wheels (not shown). The drive units are controllable to operate the vehicle 10 in various operating modes, such as a normal mode, a high-performance mode (in which additional torque is applied), all-wheel drive (“AWD”), front-wheel drive (“FWD”), rear-wheel drive (“RWD”) and others.

For example, the propulsion system 16 is a multi-drive system that includes a front drive unit 20 for driving front wheels, and rear drive units for driving rear wheels. The front drive unit 20 includes a front electric motor 22 and a front inverter 24 (e.g., front power inverter module or FPIM), as well as other components such as a cooling system. A left rear drive unit 30L includes a left rear electric motor 32L and a left rear inverter 34L. A right rear drive unit 30R includes a right rear electric motor 32R and a right rear inverter 34R. The front inverter 24, left rear inverter 34L and right rear inverter 34R (e.g., power inverter units or PIMs) each convert direct current (DC) power from a high voltage (HV) battery system 40 to poly-phase (e.g., two-phase, three-phase, six-phase, etc.) alternating current (AC) power to drive the front electric motor 22 the left rear electric motor 32L and the right rear electric motor 32R.

As shown in FIG. 1, the drive systems feature separate electric motors. However, embodiments are not so limited. For example, instead of separate motors, multiple drives can be provided by a single machine that has multiple sets of windings that are physically independent.

As also shown in FIG. 1, the drive systems are configured such that the front electric motor 22 drives the front wheels (not shown), and the left rear electric motor 32L and right rear electric motor 32R drive the rear wheels (not shown). However, embodiments are not so limited, as there may be any number of drive systems and/or motors at various locations (e.g., a motor driving each wheel, twin motors per axle, etc.). In addition, embodiments are not limited to a dual drive system, as embodiments can be used with a vehicle having any number of motors and/or power inverters.

In the propulsion system 16, the front drive unit 20, left rear drive unit 30L and right rear drive unit 30R are electrically connected to the battery system 40. The battery system 40 may also be electrically connected to other electrical components (also referred to as “electrical loads”), such as vehicle electronics (e.g., via an auxiliary power module or APM 42), heaters, cooling systems and others. The battery system 40 may be configured as a rechargeable energy storage system (RESS).

In an embodiment, the battery system 40 includes a plurality of separate battery assemblies, in which each battery assembly can be independently charged and can be used to independently supply power to a drive system or systems. For example, the battery system 40 includes a first battery assembly such as a first battery pack 44 connected to the front inverter 24, and a second battery pack 46. The first battery pack 44 includes a first plurality of battery modules 48, and the second battery pack 46 includes a second plurality of battery modules 50. Each of the first plurality of battery modules 48 and the second plurality of battery modules 50 includes a number of individual cells (not shown).

Each of the front electric motor 22 and the left rear electric motor 32L and right rear electric motor 32R is a three-phase motor having three phase motor windings. However, embodiments described herein are not so limited. For example, the motors may be any poly-phase machines supplied by poly-phase inverters, and the drive units can be realized using a single machine having independent sets of windings.

The battery system 40 and/or the propulsion system 16 includes a switching system having various switching devices for controlling operation of the first battery pack 44 and second battery pack 46, and selectively connecting the first battery pack 44 and second battery pack 46 to the front drive unit 20, left rear drive unit 30L and right rear drive unit 30R. The switching devices may also be operated to selectively connect the first battery pack 44 and the second battery pack 46 to a charging system. The charging system can be used to charge the first battery pack 44 and the second battery pack 46, and/or to supply power from the first battery pack 44 and/or the second battery pack 46 to charge another energy storage system (e.g., vehicle-to-vehicle (V2V) and/or vehicle-to-everything (V2X) charging). The charging system includes one or more charging modules. For example, a first onboard charging module (OBCM) 52 is electrically connected to a charge port 54 for charging to and from an AC system or device, such as a utility AC power supply. A second OBCM 53 may be included for DC charging (e.g., DC fast charging or DCFC).

In an embodiment, the switching system includes a first switching device 60 that selectively connects to the first battery pack 44 to the front inverter 24, left rear inverter 34L and right rear inverter 34R, and a second switching device 62 that selectively connects the second battery pack 46 to the front inverter 24, left rear inverter 34L and right rear inverter 34R. The switching system also includes a third switching device 64 (also referred to as a “battery switching device”) for selectively connecting the first battery pack 44 to the second battery pack 46 in series.

Any of various controllers can be used to control functions of the battery system 40, the switching system and the drive units. A controller includes any suitable processing device or unit, and may use an existing controller such as a drive system controller, an RESS controller, and/or controllers in the drive system. For example, a controller 65 may be included for controlling various operations of the vehicle and the battery pack, as discussed herein.

The vehicle 10 also includes a computer system 55 that includes one or more processing devices 56 and a user interface 58. The computer system 55 may communicate with the charging system controller, for example, to provide commands thereto in response to a user input. The various processing devices, modules and units may communicate with one another via a communication device or system, such as a controller area network (CAN) or transmission control protocol (TCP) bus.

As illustrated herein, the vehicle 10 is an electric vehicle. In an alternative embodiment, the vehicle 10 can be an internal combustion engine vehicle, a hybrid vehicle, etc.

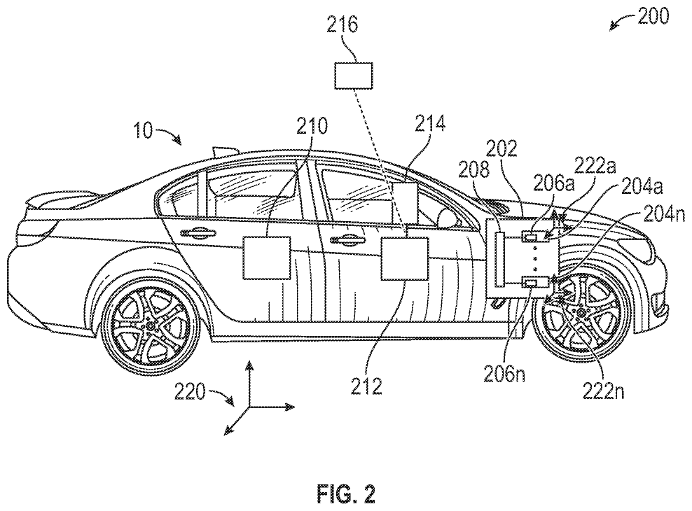

FIG. 2 shows a battery health diagnosis system 200 of the vehicle 10, in an embodiment. The battery health diagnosis system 200 determines a health of a battery unit and determines an action to take based on the health of the battery unit. A battery unit can be a battery pack, battery modules. or other battery subsystems such as a Battery Disconnect unit (BDU), a Cell Management Unit (CMU), an On-Board Charging Module (OBCM), etc. For illustrative purposes, the battery health diagnosis system 200 is discussed with respect to a battery pack 202. The battery pack 202 includes battery modules 204a-204n. Each of the battery modules 204a-204n includes an accelerometer 206a-206n. Each accelerometer measures the accelerations or forces experienced at its associated battery module. Each accelerometer 206a-206n is a component of the battery health diagnosis system 200. The battery pack 202 includes an interface 208 which couples each accelerometer to other components of the battery health diagnosis system 200.

The battery health diagnosis system 200 includes the accelerometers 206a-206n, a vehicle dynamics sensor 210, a controller 212, and a human machine interface 214. The controller 212 may include processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. The controller 212 may include a non-transitory computer-readable medium that stores instructions which, when processed by one or more processors of the controller 212, implement a method of determining a health status of a battery pack and operating the vehicle based on the health status, according to one or more embodiments detailed herein.

The controller 212 can be in communication with a remote server 216. The vehicle dynamics sensor 210 records vehicle dynamics data in a vehicle-centered frame of reference 220 (along three axes of the vehicle). The vehicle dynamics data includes vehicle acceleration, vehicle velocity (linear and radial), vehicle direction and spatial orientation, etc. The vehicle dynamics data can be gyroscope data, in an embodiment.

Each of the accelerometers 206a-206n has an associated unit-centered frame of reference 222a-222n and records battery module data in the associated unit-centered frame of reference. The battery module data includes accelerations and/or forces experienced at each of the battery modules.

The vehicle dynamics sensor 210 and the accelerometers 206a-206n can record their respective data over a moving window. When an impact event occurs at the vehicle, the data within the moving window at the vehicle dynamics sensor 210 and the accelerometers 206a-206n is stored and sent to the controller 212. The controller 212 inputs the vehicle dynamics data and the battery module acceleration data to a model which outputs an inertial load on the battery modules 204a-204n. The inertial load for a battery module includes the magnitude and direction of forces and/or accelerations on the battery module.

The controller 212 compares the inertial loads to a virtual model of the battery unit (e.g., battery pack and battery modules) and determines an action to take based on the comparison. The virtual model is a model of the battery unit. The virtual model can be created at the remote server 216 and the simulation can be performed on the virtual model using various simulated loads and forces to determine a state of the virtual model during one or more impact events that include the simulated loads and forces. Each simulation of an impact event can be evaluated to determine the amount of damage that occurs to the battery unit due to the impact event. The results of the simulated damage can be used to establish one or more thresholds indicating a remedial action to take in the presence of an impact event.

In various embodiments, the simulation establishes a plurality of thresholds. A first threshold can be a critical threshold or high impact threshold that indicates major damage to the battery unit. If the inertial load on a battery unit is greater than the first threshold, the controller 212 can shut down the battery unit. A second threshold can indicate that the battery unit has experienced minor damage. If the inertial load on the battery module is greater than the second threshold (but less than the first threshold), the controller 212 can keep operating using the battery unit and send a signal to the occupant or driver of the vehicle that service is needed. Although only two thresholds are discussed, it understood that there can be any number of thresholds, with each threshold defining a health status of the unit module and having an associated remedial action for addressing the health status.

For a battery pack, the controller 212 can shut down the entire battery pack based on an analysis of the health of each of the battery modules. In addition, when a first battery module has a first health status and a second battery module has second health status, the processor can provide a first remedial action for the first battery module and a second remedial action for the second battery module. As an example, when the health of the first battery module indicates major damage and the health of the second battery module indicates minor damage, the processor can turn off the first battery module and keep using the second battery module.

In another example, the controller 212 can send a signal to the human machine interface 214 to alert the driver or occupant of the vehicle of the need to get the battery pack serviced.

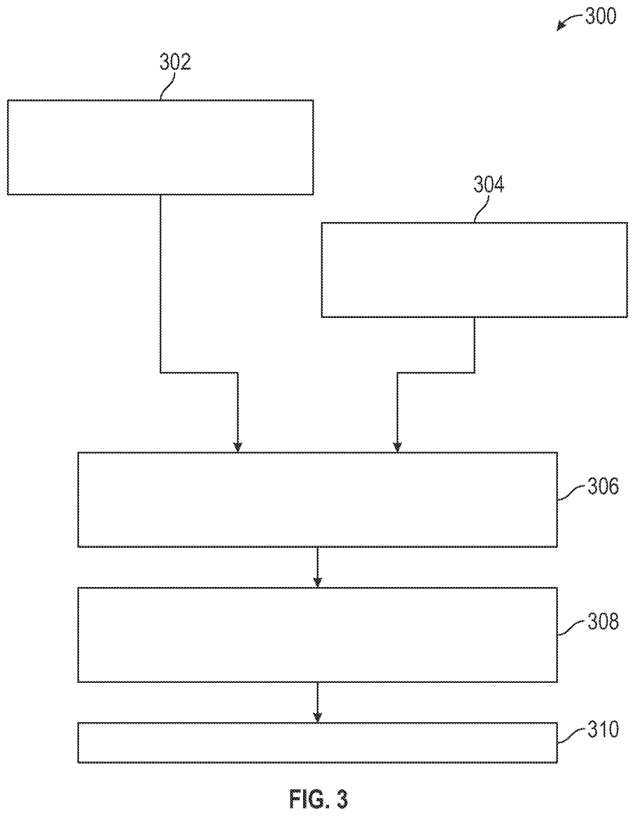

FIG. 3 is a flowchart 300 of a method of operating a battery pack of a vehicle, in an illustrative embodiment. In box 302, vehicle dynamics data is obtained during an impact event. In box 304, battery unit acceleration data is obtained during the impact event. In box 306, the vehicle dynamics data and the battery unit acceleration data are sent through a model to determine an inertial load on the battery module. In box 308, the inertial load is compared to a threshold. The threshold is determined using a pre-determined and/or defined simulation of the battery module. The comparison results in an output indicative of the health of the battery unit. In box 310, a remedial action is performed based on the health of the battery unit. The simulation can be performed offline while the health status is determined online.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method for diagnosing a health of a battery pack of a vehicle, comprising:
obtaining a vehicle dynamics data for the vehicle during a time period in which an impact event occurs at the vehicle;
obtaining a battery unit acceleration data for a battery unit of the vehicle during the time period;
determining an inertial load on the battery unit from the vehicle dynamics data and the battery unit acceleration data;
comparing the inertial load to a threshold determined using a virtual model of the battery unit to determine a health status of the battery unit; and
performing a remedial action for the battery unit based on the health status.

2. The method of claim 1, further comprising simulating the impact event using the virtual model to determine the threshold.

3. The method of claim 2, further comprising simulating the impact event offline and determining the health status online.

4. The method of claim 1, further comprising determining the health based on a magnitude of the inertial load and a direction of the inertial load.

5. The method of claim 1, further comprising obtaining the vehicle dynamics data in a vehicle-centered frame of reference and obtaining the battery unit acceleration data in a unit-centered frame of reference.

6. The method of claim 1, wherein performing the remedial action further comprises at least one of: (i) sending a signal indicating the health of the battery unit; (ii) sending the signal instructing an operator of the battery unit; (iii) shutting down the battery unit; and (iv) shutting down a battery pack.

7. The method of claim 1, wherein the battery unit includes a plurality of battery units, further comprising obtaining the battery unit acceleration data for each of the plurality of battery units, determining the health status for each of the plurality of battery units based on the respective battery unit acceleration data and performing the remedial action for each battery unit based on the health status of the respective battery unit.

8. A system for diagnosing a health of a battery unit of a vehicle, comprising:
a vehicle dynamics sensor for measuring vehicle dynamics data for the vehicle during a time period in which an impact event occurs at the vehicle;
an accelerometer for obtaining a battery unit acceleration data for the battery unit during the time period;
a processor configured to:
determine an inertial load on the battery unit from the vehicle dynamics data and the battery unit acceleration data;
compare the inertial load to a threshold determined using a virtual model of the battery unit to determine a health status of the battery unit; and
perform a remedial action for the battery unit based on the health status.

9. The system of claim 8, wherein the processor is further configured to simulate the impact event using the virtual model to determine the threshold.

10. The system of claim 9, wherein the processor is further configured to simulate the impact event offline and determine the health status online.

11. The system of claim 8, wherein the processor is further configured to determine the health based on a magnitude of the inertial load and a direction of the inertial load.

12. The system of claim 8, wherein the vehicle dynamics sensor is configured to measure the vehicle dynamics data in a vehicle-centered frame of reference and the accelerometer is configured obtain the battery unit acceleration data in a unit-centered frame of reference.

13. The system of claim 8, wherein the processor is further configured to perform the remedial action by performing at least one of: (i) sending a signal indicating the health of the battery unit; (ii) sending the signal instructing an operator of the battery unit; (iii) shutting down the battery unit; and (iv) shutting down a battery pack.

14. The system of claim 8, wherein the battery unit includes a plurality of battery units, wherein the processor is further configured to obtain the battery unit acceleration data for each of the plurality of battery units, determine the health status for each of the plurality of battery units based on the respective battery unit acceleration data and perform the remedial action for each battery unit based on the health status of the respective battery unit.

15. A vehicle, comprising:
a battery pack;
a vehicle dynamics sensor for measuring vehicle dynamics data for the vehicle during a time period in which an impact event occurs at the vehicle;
an accelerometer for obtaining a battery unit acceleration data for a battery module of the battery pack during the time period;
a processor configured to:
determine an inertial load on the battery module from the vehicle dynamics data and the battery unit acceleration data;
compare the inertial load to a threshold determined using a virtual model of the battery pack to determine a health status of the battery pack; and
perform a remedial action for the battery pack based on the health status.

16. The vehicle of claim 15, wherein the processor is further configured to simulate the impact event using the virtual model to determine the threshold.

17. The vehicle of claim 16, wherein the processor is further configured to simulate the impact event offline and determine the health status online.

18. The vehicle of claim 15, wherein the processor is further configured to determine the health status of the battery pack based on a magnitude of the inertial load and a direction of the inertial load.

19. The vehicle of claim 15, wherein the vehicle dynamics sensor is configured to measure the vehicle dynamics data in a vehicle-centered frame of reference and the accelerometer is configured to obtain the battery unit acceleration data in a unit-centered frame of reference.

20. The vehicle of claim 15, wherein the processor is further configured to perform the remedial action by performing at least one of: (i) sending a signal indicating the health status of the battery pack; (ii) sending the signal instructing an operator of the battery module; (iii) shutting down the battery module; and (iv) shutting down the battery pack.
